(19) United States
(12) Patent Application Publication
(10) Pub. No.: US 2013/0312830 A1
(43) Pub. Date: Nov. 28, 2013

(54) Photovoltaic Element With An Included Resonator

(71) Applicant: Fiala Pavel, Brno (CZ)

(72) Inventor: Fiala Pavel, Brno (CZ)

(21) Appl. No.: 13/981,881

(22) PCT Filed: Aug. 3, 2011
(86) PCT No.: PCT/CZ11/00076

§ 371 Date: Jul. 25, 2013

(30) Foreign Application Priority Data
Jan. 27, 2011 (CZ) PV 2011-45

(51) Int. Cl. H01L 31/0232

(52) U.S. Cl. CPC H01L 31/0232
USPC 136/259

(57) ABSTRACT

A photovoltaic element including a resonator is arranged on a semiconductor structure (5) that is constituted by a region without electromagnetic damping (5a), whose upper plane forms the plane of incidence (3), and a region with electromagnetic damping (5b), both regions being bound by virtual boundaries (6) of variation in material properties. At least one 2D-3D resonator (4) is surrounded by a dielectric (10) and configured on the semiconductor structure (5), with a relative electrode (11) bordering on the region with electromagnetic damping (5b). The photovoltaic element having a resonator arranged on a semiconductor structure (5) uses the structure (5) and its characteristics to set suitable conditions for the impingement of an electromagnetic wave and its transformation to a stationary form of the electromagnetic field and not to secure the generation of an electric charge. The 2D-3D resonator produces electric current or voltage, which is conducted with the help of a nonlinear component (15) to a connecting component (16). The nonlinear element (15) shapes the signal on the resonant circuit; this signal is then filtered (rectified) to a further utilizable shape. The planar and spatial resonator (2D-3D resonator) is designed in such a manner that prevents the electromagnetic wave passing through the semiconductor structure (5) from being reflected back to the 2D-3D resonator created in the structure (5). The semiconductor structure (5) does not generate a backward electromagnetic wave propagating in the direction of the impinging electromagnetic wave emitted by a source such as the Sun. The region with electromagnetic damping (5b) has the function of suppressing the reflected wave. Thus, the resonator behaves like an ideal impedance-matched component for the proposed frequency spectrum. The semiconductor structure (5) is set in such a manner that the conductivity increases in the electromagnetic damping region (5b) in the direction of the relative electrode (11), which leads to a wide resonance curve in the photovoltaic element components.

### TECHNICAL FIELD OF THE INVENTION

The invention relates to a photovoltaic element including a resonator and characterized by a high rate of efficiency related to the transformation of the energy of light to electric energy, the element comprising a semiconductor structure located between two electrodes.

### STATE OF THE ART

In contemporary photovoltaics, more than fifty-year-old principles of transforming solar electromagnetic radiation (wideband electromagnetic radiation within the wavelength range of 100 nm to 10000 nm) are generally applied. The solar cells are composed of two semiconductor layers (with silicon being the usual material) located between two metal electrodes. One of the layers (an N-type material) comprises a multitude of negatively charged electrons, whereas the other layer (a P-type material) shows a large number of “holes” definable as void spaces that easily accept electrons. Devices transforming electromagnetic waves to a lower-frequency electromagnetic wave, or a direct component, are known as transvertors/converters. For this purpose, semiconductor structures with differing concepts and types of architecture are applied, respecting only experimental results of the electromagnetic wave transformation effect. The antennas, detectors, or structures designed to date are not tuned into resonance; the applied semiconductor structures face considerable difficulty in dealing with emerging stationary electromagnetic waves.

Similar solutions utilize the principles of antennas as well as the transformation of a progressive electromagnetic wave to another type of electromagnetic radiation (namely a progressive electromagnetic wave having different polarization or a stationary electromagnetic wave) and its subsequent processing. Certain problems occur in connection with the impinging electromagnetic wave and its reflection as well as in relation to the wide-spectrum character of solar radiation. In general, it is not easy to construct an antenna capable of maintaining the designed characteristics in the wide spectrum for the period of several decades.

### SUMMARY OF THE INVENTION

The invention is aimed to propose a new architecture of a photovoltaic element having a resonator arranged on a semiconductor structure. Based on the utilized construction technique, the element resonates and produces high-value components of the electric and magnetic fields in such a manner that these components are ulitizable and processible by means of the well-known technology based on classical semiconductors.

The above-mentioned drawbacks are eliminated by a photovoltaic element including a resonator that comprises a semiconductor structure characterised in that the semiconductor structure is formed by a region without electromagnetic damping, whose upper plane constitutes the incidence plane, and an electromagnetic damping region, both the regions are bounded by virtual (assumed) boundaries of the changes of material properties, while at least one 2D-3D resonator is surrounded by a dielectric and arranged in the semiconductor structure; in the direction of the electromagnetic wave propagation, the electromagnetic damping region borders on the relative electrode.

The creation of high-value components of the electric and magnetic fields can be realized conveniently when the 2D-3D resonator is composed of two parts, of which the first (2D) part, is constituted by a transformation element arranged on the incidence plane and consisting of a pair of electrodes in the form of coupled conductors, while the second (3D) part is constituted by a dielectric and a reflector, which is arranged both inside the region without electromagnetic damping and inside the region with electromagnetic clamping, while the transformation element is further arranged on the dielectric, upon which the reflector is placed orthogonally.

The invention utilizes the spectrum of solar radiation in which the electromagnetic wave power flow density (W/m²) is high. Within the presented invention, the photovoltaic element in the form of a resonator arranged on a semiconductor structure is characterised by a high rate of efficiency related to the transformation of the energy of light to electric energy.

The main advantage of the newly constructed photovoltaic element with semiconductor structure consists in the manner of its composition, namely in the planar and spatial resonator (2D-3D resonator), which is part of the semiconductor structure. This structure does not generate a backward electromagnetic wave propagating in the direction of the impinging electromagnetic wave emitted by a source such as the Sun. The 2D-3D resonator is designed in such a manner that prevents the electromagnetic wave passing through the semiconductor structure from being reflected back to the 2D-3D resonator created in the structure. Thus, the resonator behaves like an ideal impedance-matched component for the proposed frequency spectrum.

The semiconductor structure on which the 2D-3D resonator is arranged consists of two parts, namely a region without electromagnetic damping and a region with electromagnetic damping, which are bounded by the planes of variation in material properties, while, the region with electromagnetic damping has the function of suppressing the reflected wave. At least one 2D-3D resonator is arranged on the incidence plane which, in this case, is identical with the plane of variation in material properties. These parts ensure optimal processing of the electromagnetic wave; the processing is realized in such a way that the occurrence of a reflected wave towards the 2D-3D resonator is prevented. Behind the electromagnetic damping region, which ends at the plane of variation in material properties, there follows the arranged relative electrode.

Importantly, the photovoltaic element having a resonator arranged on a semiconductor structure does not utilize the structure and its characteristics to secure the generation of an electric charge, but rather uses both these aspects to set suitable conditions for the impingement of an electromagnetic wave and its transformation to a stationary form of the electromagnetic field.

Another advantage consists in the fact that the donor material will induce an increased of gama conductivity [S/m] in the semiconductor structure material. This structure is set in order for the conductivity to increase, in the electromagnetic damping region, in the direction of the relative electrode. Thus, the photovoltaic element components arranged on the semiconductive structure behave in such a way that they create a wide resonance curve (FIG. 10). This enables us—in comparison with cases when the semiconducting material is hot modified as described above, FIG. 9—to comprise the desired frequency spectrum of the impinging electromagnetic wave using a markedly lower number of variants of tuned semiconducting structures within the complex of the designed structure.

Based on the, presented invention, the described solution allows the adaptation of individual photovoltaic elements in the resulting structure to density conditions of the impinging electromagnetic radiation as present at the location where the elements are applied. In consequence of this characteristic, it is possible for us to utilize (harvest) the maximum energy of the incident electromagnetic radiation and to profit from the change of the radiation to the required form of energy that provides for further application (for example, as an electric energy source or generator). The designed photovoltaic elements including resonators are imbedded in panels which, when interconnected, form photovoltaic fields.

### BRIEF DESCRIPTION OF THE DRAWINGS

The principle of the invention will be clarified through the use of drawings, where

FIG. 1 describes the basic configuration of a photovoltaic element with a 2D-3D resonator,

FIG. 2 illustrates the exemplary embodiment of a photovoltaic element including a system of 2D-3D resonators and connecting components arranged on a semiconductor structure,

FIG. 3 shows a schematic view of a 2D-3D resonator arranged on a semiconductor structure,

FIG. 4 represents the configuration of a 2D-3D resonator and reflector,

FIG. 5 describes the partial spatial arrangement of a 2D-3D resonator in the dielectric and reflector region within the semiconductor structure of a photovoltaic element,

FIG. 6a illustrates the axonometric view of a resonator (formed by a reflector) above which the dielectric and the transformation component are arranged,

FIG. 6b shows a lateral view of a resonator,

FIG. 7a represents the connection of a transformation component with a nonlinear component in the forward direction,

FIG. 7b describes the connection of a transformation component with a nonlinear component in the backward direction,

FIG. 8 shows the resonant circuit connection (the circuit consists of a photovoltaic element and related electronics),

FIG. 9 illustrates the resonance curve of a classical resonator, and

FIG. 10 provides the resonance curve of the proposed resonator.

### EXEMPLARY EMBODIMENT OF THE INVENTION

The principle of constructing a photovoltaic element with a resonator arranged on a semiconductor structure will be clarified by but not limited to the examples provided below.

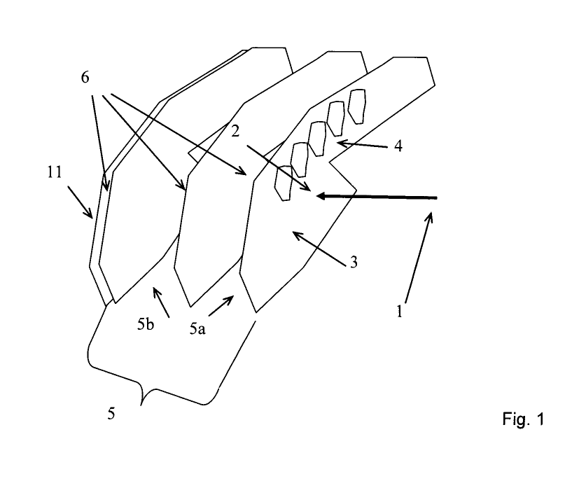

The basic version of a 2D-3D resonator arranged on a semiconductor structure is provided in FIG. 1. This form of a photovoltaic element includes a semiconductor structure 5, which consists of two parts. These two parts constitute the region 5a without electromagnetic damping and the region 5b with electromagnetic damping, both of which are bounded by virtual (assumed) boundaries 6 of variation in material properties. Furthermore, the semiconductor structure 5 includes at least one 2D-3D resonator 4 arranged on the incidence plane 3, which, in this case, is identical with the boundary 6 of variation in material properties. After the electromagnetic damping region 5b, which is bounded from both sides by the boundary 6 of variation in material properties, there follows the arranged relative electrode 11.

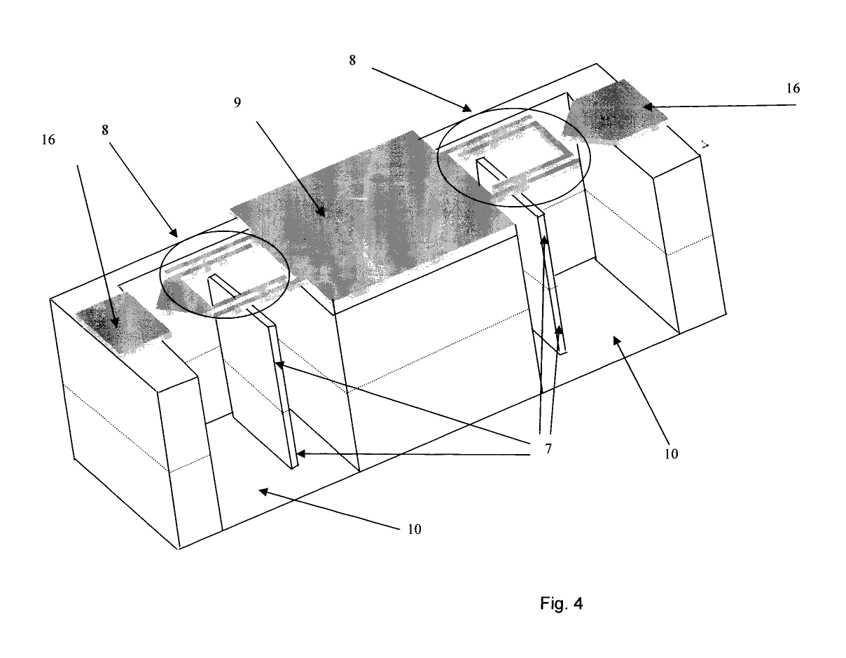

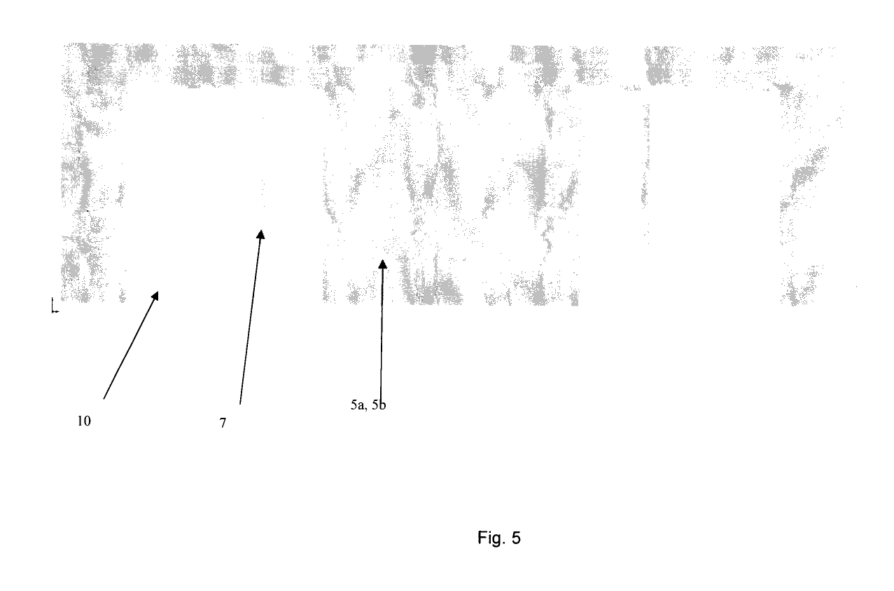

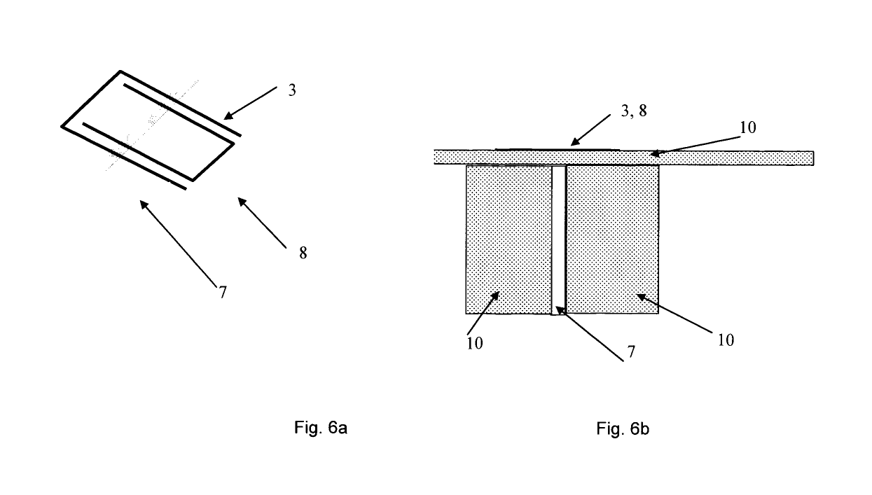

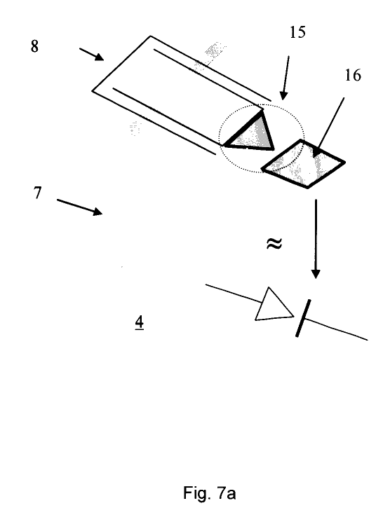

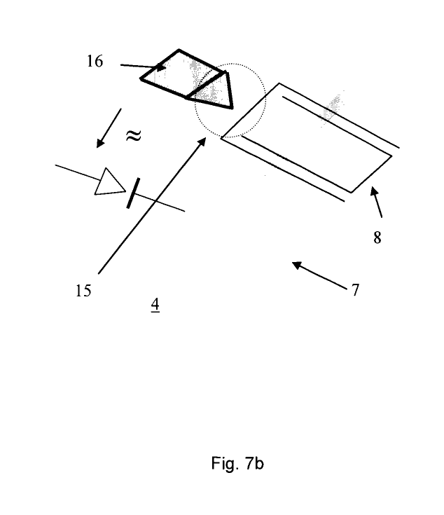

The 2D-3D resonator 4 is described in FIG. 4, FIG. 6a and FIG. 6b. This version of the 2D-3D resonator 4 consists of a transformation component 8 and a reflector 7, between which the dielectric 10 (such as an insulant) is arranged, with the transformation component 8 constituted by a pair of electrodes in the form of coupled conductors surrounded by the dielectric 10. Furthermore, the transformation component 8 is arranged on the dielectric 10, upon which the reflector 7 is placed orthogonally. FIG. 5 shows the arrangement of the dielectric 10 in the semiconductor structure. The 2D-3D resonator 4 produces electric current or voltage, which is conducted by the help of a nonlinear component 15 to the connecting component 16; this situation can be seen in FIGS. 7a and 7b, where both types of the nonlinear component 15 polarization are described.

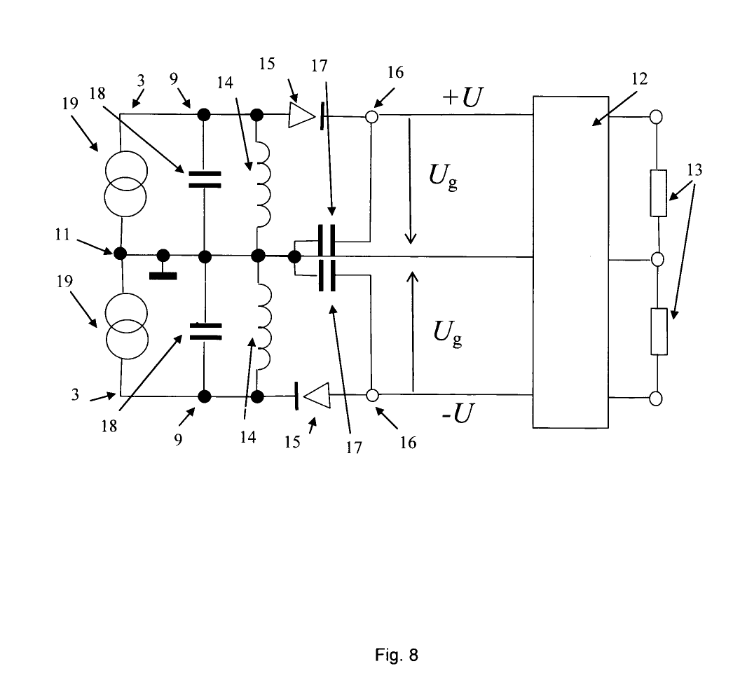

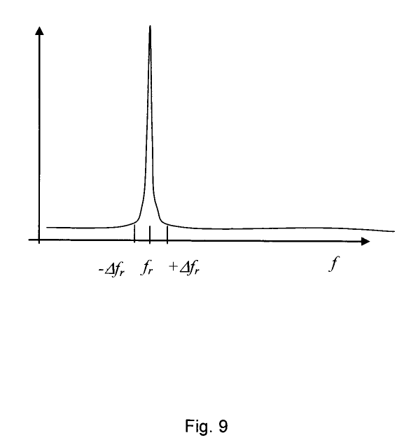

FIG. 8 represents an electrical alternate diagram of the photovoltaic element. The variants concerned are principially a one-way or two-way rectifier, a shaper, or a signal filter. These types of connection are widely known. A source 19 of alternating current or voltages caused by induction from an electromagnetic wave is connected parallelly to the first capacitor 18 and the inductor 14, which in the connection are constituted by a condenser and a coil. These components then create a tuned alternating circuit (a circuit which is tuned to the characteristics and parameters of the impinging electromagnetic wave and which resonates). The nonlinear element 15 shapes the signal on the resonant circuit; this signal is then filtered (rectified) to a further utilizable shape. As the next step, connection to the second capacitor 17 is realized; in the connection, the capacitor is constituted by a condenser. Also, in the connection, connecting components 16 are indicated. These components 16 show electric voltage +U, −U. If a selected electrical load 13 in the form of impedance Z is connected to the connecting components 16 (such as clamps), a variation in the resonant circuit occurs and the resonator may change its characteristics to such an extent that it will not be in a suitable resonance mode. Therefore, a device 12 is introduced before the electrical load 13. With any loading by electrical impedance Z on its output, this device will cause the situation when, on the output, the resonator with the nonlinear component 15 and the second capacitor 17 is loaded by one and the same value of impedance Zi, which will not change the set mode of the resonator.

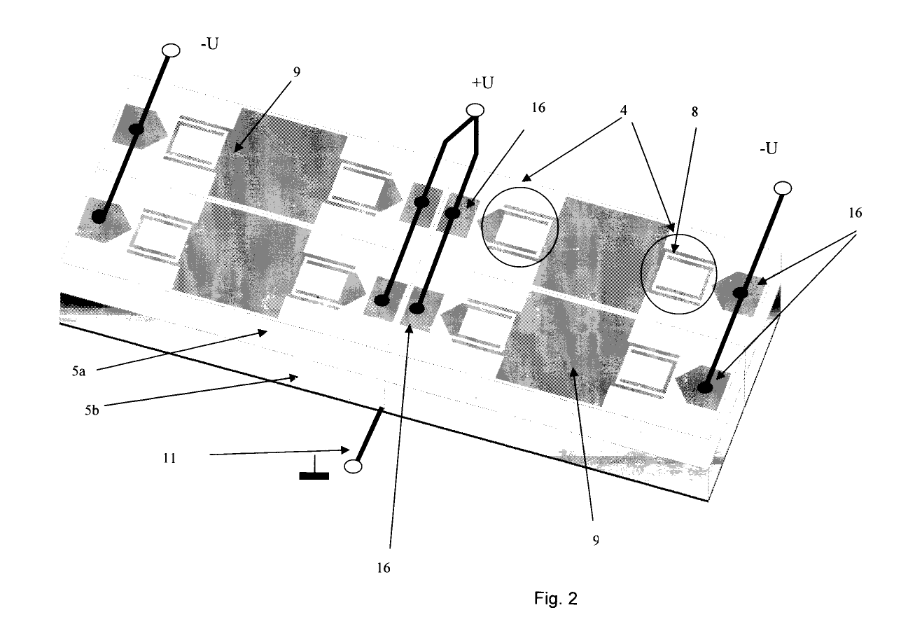

The function (or operation) of the photovoltaic element, which includes a 2D-3D resonator 4 arranged on a semiconductor structure 5, is as follows: An electromagnetic wave 1 within the wavelength range of 100 nm to 100000 nm impinges at the wave incidence point 2 on the incidence plane 3 of the designed photovoltaic element. The 2D-3D resonator 4 is periodically repeated (as described in FIG. 1 and FIG. 2). In the photovoltaic element incidence plane 3, the formation of at least one 2D-3D resonator 4 is arranged. This resonator may operate (perform its function) individually; alternatively, we can realize an interconnection between the resonators, thus creating a field of photovoltaic elements. In the incidence plane 3, these elements are connected parallelly or in series, with the formation of at least two 2D-3D resonators 4 on one photovoltaic element appearing to be an advantageous solution. These resonators are interconnected by means of a connecting element 9.

An electromagnetic wave 1 impinges at the point of incidence 2 on the incidence plane 3. Here, the electric and magnetic components of the electromagnetic wave 1 decompose and form the maxima of intensities of the electric and the magnetic fields. This process is realized thanks to the designed shape of the reflector 7, which can be a thin layer, a cuboid, a pyramid, a cone, a toroid, or a sphere of their combination, parts, penetration. The surface of the reflector 7 may be formed by a layer of a dielectric material, metal, or a combination and shape variety of both (the components being part of the 2D-3D resonator 4). In order for the above-mentioned maxima of intensities to add up arithmetically (superpone) when a connection is realized of two periodically repeated 2D-3D resonators 4, these resonators are connected by the help of a connecting element 9 (as described in FIG. 2). This figure shows an example of the proposed photovoltaic element having a 2D-3D resonator 4 and arranged on a semiconductor structure 5, where two 2D-3D resonators 4 are arranged at the location of the incidence plane 3. These resonators are periodically repeated on other semiconductor structures 5; also, the 2D-3D resonators 4 are interconnected by means of connecting components 9.

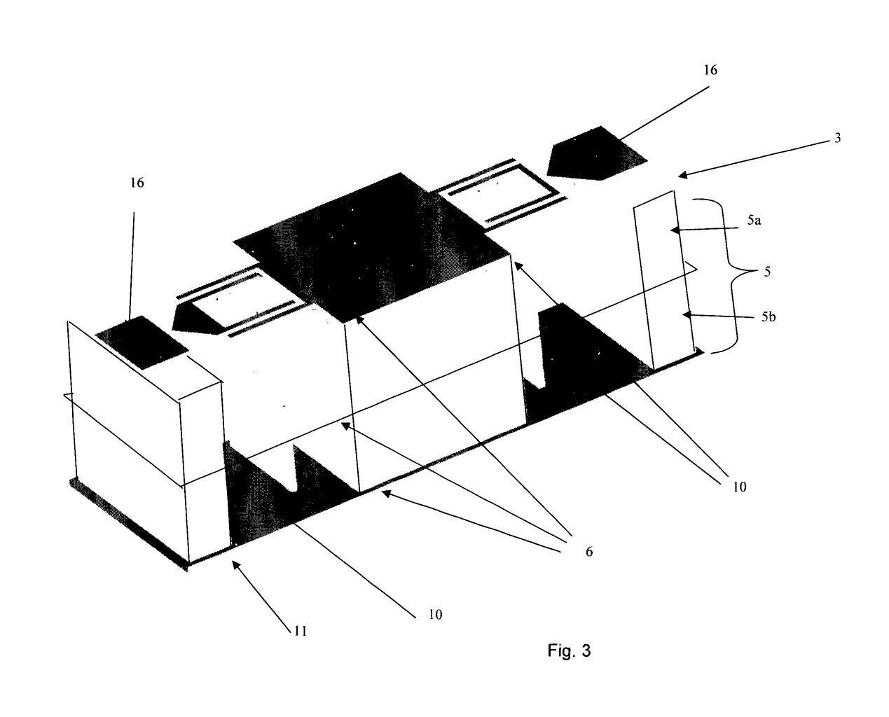

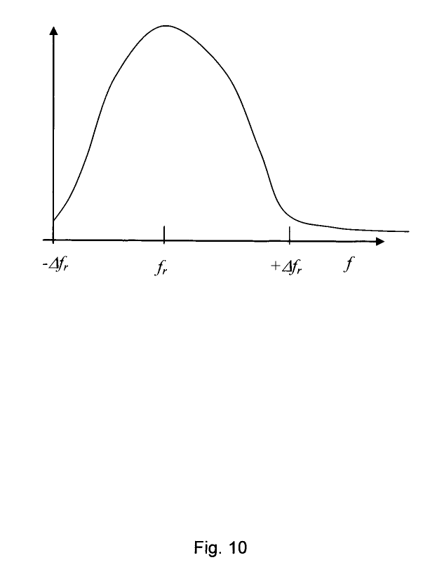

An exemplary embodiment of a photovoltaic element including a 2D-3D resonator 4 and arranged on a semiconductor structure 5 is described in FIG. 3. This version of the 2D-3D resonator 4 is arranged on a semiconductor structure 5. This structure consists of two parts, namely region 5a without electromagnetic damping and region 5b with electromagnetic damping; the parts are bounded by virtual boundaries 6 of variation in material properties. Mutual arrangement (configuration) of individual parts of the photovoltaic element is shown in FIG. 4. The 2D-3D resonator 4 consists of a transformation component 8 (which is composed of a pair of electrodes in the form of coupled conductors), a reflector 7, and a dielectric 10. The 2D-3D resonator 4 is further embedded in the semiconductor structure 5; the geometry is designed in dependence on the wavelength of the impinging electromagnetic wave, namely in such a manner that the thickness of the semiconductor structure 5 will be minimally ¼ of the wavelength of the lowest frequency of the incident electromagnetic radiation. The proposed geometry design will ensure the resulting resonance characteristic according to FIG. 10.

After impinging on the incidence plane 3, the electromagnetic wave permeates through the semiconductor structure 5. On the surface of the semiconductor structure 5 at the location of the incidence plane 3, the 2D part of the resonator 4 is modified, whereas the 3D part interferes with the semiconductor structure 5 (as illustrated in FIGS. 3 or 4). The semiconductor structure 5 is instrumental towards setting the conditions of the electrical and magnetic components maxima in the electromagnetic wave incidence plane 3. In this respect, the semiconductor structure 5 is formed by the region 5a without electromagnetic damping, whose function is to allow the advancing electromagnetic wave on the semiconductor structure 5 to link and create a resonant region with a maximum resonance in the incidence plane 3; The region 5b with electromagnetic damping is instrumental towards slow damping of the advancing electromagnetic wave, which progresses in the direction from the incidence plane 3 to internal structures of the semiconductor structure 5 and causes a condition in which there occurs minimum reflection of the progressive wave from the electrode 11 back to the semiconductor structures 5b and 5a. The main function of the electromagnetic damping region 5b is to prevent the electromagnetic wave at the end of the semiconductor structure 5 from bouncing back and allowing the generation of a stationary electromagnetic wave. The dimensions of the region without electromagnetic damping 5a as well as the region with electromagnetic damping 5b are selected to be, at the minimum, equal to or greater than one quarter of the wavelength of the impinging electromagnetic wave 1 (for example, both layers may show the thickness of 10 μm).

Through the achievement of a resonant state, there occurs in one photovoltaic element a multiple increase of amplitudes of the original impinging electromagnetic wave, and for the assumed wavelength of the electromagnetic wave 1 impinging on the incidence plane 3 of the semiconductor structure 5 we can obtain an electric voltage applicable for further processing by electronic circuits 12 that manage the performance and mode of the periodic structure designed for energy harvesting.

A high-quality conductor is applied as the material of conductive paths formed in the incidence plane 3, on which the 2D part of resonator 4 is arranged; the same high-quality conductor is also used for the connecting conductive element 9 and the material of the nonlinear element 15. The region without electromagnetic damping 5a is formed by a combination of the dielectric 10 and a conductive and/or semi-conductive material. The region with electromagnetic damping 5b is formed by a material changing the specific conductance; which increases in the direction from the electromagnetic wave 1 incidence plane 3. Specific conductance with the unit in the SI (S/m) system is, in the region with electromagnetic damping 5b, set in such a manner that the coefficient of stationary waves is less than 0.5 from the interval of <0,1>.

The designed semiconductor structure 5 of the photovoltaic element operates in the resonant state, which enables us to advantageously obtain on the resonator 4 multiple (2-1000) values of amplitude of the electric component of the impinging electromagnetic wave 1. The proposed periodic arrangement allows operation in the resonant mode for frequencies f with a change of frequency Δf. It is possible to achieve parameter Δf/f at the interval of 0.5 to 1.5.

The classical solution using antennas and standard resonant circuits usually makes it possible to achieve only the fate of Δf/f at the interval of 0.9 to 1.1. The solution proposed in this document, thanks to the absorption characteristics of the region with electromagnetic damping 5b and the dimensions with respect to the wavelength, allows the achievement of the above-noted rate of Δf/f. This condition can be advantageously utilized for the design of an optimal semiconductor structure 5 and for approaching the ideal state of 100% harvest rate as related to the transformation of the electromagnetic wave 1 impinging on the elements on the generator voltage.

A necessary prerequisite for the utilization of the basic element (at the very minimum) as an electric energy source consists in connecting the electronic external circuit 12, which allows that, at any loading (load impedance Z 13 assumes the values from the interval 0 to ∞ Ohms) of the output of the circuit 12, the variation of electrical load Zi on the input of the circuit 12 will not manifest itself. Thus, the basic component or group of components will remain in the resonant state.

### INDUSTRIAL APPLICABILITY

The described photovoltaic element can be utilized as a harvester or generator of electric energy, possibly also as a sensor or nonlinear converter.

### SUMMARY OF APPLIED REFERENTIAL SYMBOLS

1. electromagnetic wave
2. wave impingement location
3. area-plane of incidence
4. basic resonator
5. semiconductor structure
5a. region without electromagnetic damping
5b. region with electromagnetic damping
6. boundary of variation in material properties
7. basic resonator reflector
8. transformation component
9. connecting component of basic resonators
10. dielectric
11. relative electrode
12. electric circuit
13. load
14. inductor
15. nonlinear component
16. connecting component
17. second capacitor
18. first capacitor
19. Source of current or voltage caused by induction from an electromagnetic wave

1. A photovoltaic element including a resonator arranged on a semiconductor structure (5), characterised in that the semiconductor structure (5) is formed by the region without electromagnetic damping (5a), whose upper plane constitutes the incidence plane (3), and the region with electromagnetic damping (5b), both the regions are bounded by virtual boundaries (6) of variations in material properties, while at least one 2D-3D resonator (4) is arranged in the semiconductor structure (5), where its 2-D part is arranged in the incidence plane (3) and its 3-D part placed in the dielectric (10), and a relative electrode (11) borders on the region with electromagnetic damping (5b).

2. The photovoltaic element including a resonator according to claim 1, characterised in that the 2D-3D resonator (4) is formed by two parts, of which the first 2D part is constituted by a transformation element (8) arranged on the plane of incidence (3) and consisting of a pair of electrodes in the form of coupled conductors, while the second 3D part is constituted by a dielectric (10) and a reflector (7), which is arranged both inside the region without electromagnetic damping (5a) and inside the region with electromagnetic damping (5b), while the transformation component (8) is arranged on the dielectric (10), with which the reflector (7) is matched.

3. The photovoltaic element including a resonator according to claim 2, characterised in that the reflector (7) is, in relation to the dielectric (10), arranged orthogonally toward the incidence plane (3).

4. The photovoltaic element including a resonator according to claim 1, characterised in that the region with electromagnetic damping (5b), in contrast with the region without electromagnetic damping (5a), shows increasing gama conductivity [S/m] in the direction of the relative electrode (11).

5. The photovoltaic element including a resonator according to claim 2, characterised in that the region with electromagnetic damping (5b), in contrast with the region without electromagnetic damping (5a), shows increasing gama conductivity [S/m] in the direction of the relative electrode (11).

6. The photovoltaic element including a resonator according to claim 3, characterised in that the region with electromagnetic damping (5b), in contrast with the region without electromagnetic damping (5a), shows increasing gama conductivity [S/m] in the direction of the relative electrode (11).
